(19) United States
(12) Patent Application Publication
(10) Pub. No.: US 2024/0136002 A1
(43) Pub. Date: Apr. 25, 2024

(54) SIMULTANEOUS STATISTICAL MULTI-SUBBLOCK VERIFY FOR NAND MEMORIES

(71) Applicant: Intel NDTM US LLC, Santa Clara, CA (US)

(72) Inventors: Tarek Ahmed AMEEN BESHARI, San Jose, CA (US); Shantanu R. RAJWADE, San Mateo, CA (US); Violante MOSCHIANO, Avezzano (IT); Ali KHAKIFIROOZ, Brookline, MA (US); Sagar UPADHYAY, Folsom, CA (US); Giuseppina PUZZILLI, Boise, ID (US); Kartik GANAPATHI, San Jose, CA (US)

(21) Appl. No.: 18/395,540

(22) Filed: Dec. 23, 2023

(51) Int. Cl. G11C 16/34; G11C 16/24; G11C 16/26

(52) U.S. Cl. CPC G11C 16/3459; G11C 16/24; G11C 16/26

(57) ABSTRACT

Program verify can be performed simultaneously on multiple subblocks in a storage device. The program verify occurs after a program operation of the storage cells. The program verify can include application of a verify read pulse to multiple subblocks simultaneously and then a count a number of bitlines of the multiple subblocks that do not discharge in response to the verify read pulse. The program verify passes if the count is within an expected range, instead of requiring all storage cells to pass program verify before moving on. If the number of bitlines not discharging is outside the expected range, the system can perform a second program pass.

### TECHNICAL FIELD

Descriptions are generally related to storage devices, and more particular descriptions are related to verify operation for storage media.

### BACKGROUND OF THE INVENTION

Nonvolatile memory such as NAND flash memory is commonly used in storage devices. The cells of most storage devices store can store multiple data bits per cell. More specifically, the storage devices typically have different modes of operation, where the cells can be treated as SLC (single level cell) for data caching, or the cells can be configured to store multiple bits (e.g., TLC (triple level cell), QLC (quad level cell)).

The program of the cell in SLC mode is very fast compared to MLC (multilevel cell) modes. However, even in SLC mode, a significant portion of the program time is spent only for program verify. The SLC program loop includes a program pulse to set the cell state, and the verify to read the programmed cells to check that the cells have been properly programmed with the desired voltage level. The verify is a double-check operation used to determine the need for additional program pulses.

SLC programming algorithms spend only one programming loop per page for normal pages, and would spend more loops for the remaining pages. With current technologies, approximately 99% of pages end up being “non-sampling pages,” needing only a single program pass, meaning only 1% of pages are “sampling pages,” needing more than one program pass to correctly set the desired state.

NAND trims are typically calibrated to maintain a 100% non-sampling single loop for SLC programming. With such high calibration, in SLC programming, the verify becomes little more than a quality check, useful only in the rare occurrence of needing a second pulse, or to report a status fail due to operational fault.

There are systems that can store the data of the pages to verify in the SPB (static page buffer). However, verification through use of the SPB limits the number of pages that can be verified simultaneously. Assuming the SPB has a capacity of 4 pages, the system can verify up to 4 pages simultaneously, but they must be sensed separately, which requires a significantly longer verify time than the traditional verify. Additionally, verification through use of the SPB requires a more complicated algorithm adds system overhead as well as increasing design complexity.

### BRIEF DESCRIPTION OF THE DRAWINGS

The following description includes discussion of figures having illustrations given by way of example of an implementation. The drawings should be understood by way of example, and not by way of limitation. As used herein, references to one or more examples are to be understood as describing a particular feature, structure, or characteristic included in at least one implementation of the invention. Phrases such as “in one example” or “in an alternative example” appearing herein provide examples of implementations of the invention, and do not necessarily all refer to the same implementation. However, they are also not necessarily mutually exclusive.

FIG. 1 is a block diagram of an example of a system with a storage device having multiple decks.

FIG. 2A is a block diagram of an example of a system having a storage array in which multideck program verify can be implemented.

FIG. 2B is a block diagram of an example of a circuit structure for the system of FIG. 2A.

FIGS. 3A-3B are plots of examples of program verify.

FIGS. 4A-4C are diagrams of representations of pass rates for number of subblocks verified simultaneously.

FIG. 5 is a flow diagram of a process for multideck program verify.

FIG. 6A is a block diagram of an example of a system with a solid state drive (SSD) in which multideck program verify can be implemented.

FIG. 6B is a block diagram of an example of a system with a solid state drive (SSD) with a controller to manage multideck program verify.

FIG. 7 is a block diagram of an example of a computing system in which multideck program verify can be implemented.

FIG. 8 is a block diagram of an example of a mobile device in which multideck program verify can be implemented.

FIG. 9 is a block diagram of an example of a multi-node network in which multideck program verify can be implemented.

Descriptions of certain details and implementations follow, including non-limiting descriptions of the figures, which may depict some or all examples, and well as other potential implementations.

### DETAILED DESCRIPTION OF THE INVENTION

As described herein, a system can perform ultra-fast programming by performing program verify operations on many subblocks in parallel. While the case is made above that program verify is only for rare conditions, removing the verify completely would require strong statistical evidence that such operating faults resulting in wrong successful program status would not exceed error specifications. The risk of removing the verify may not be justified, as such an operation could result in increases in device error rates.

However, verify does not need to be completely removed to significantly increase the program time. With reasonable effort, a system can have enough statistical information to partially eliminate program verify by simultaneously performing verify on multiple subblocks in a storage device. The information allows for a simple, probabilistic approach to the verify operation.

A NAND storage cell is coupled between a bitline and a wordline. In a 3D (three-dimensional) NAND array, the wordlines are vertically stacked, and the cells are formed at the intersection of a wordline with a vertical pillar/channel that connects to the bitline. The application of a verify pulse creates a voltage potential between the bitline and wordline. When a cell is programmed, the cell will have a voltage potential stored that will prevent a current flow through the cell. When a cell is erased, current will flow, discharging the bitline.

NAND controllers perform operations related to “healthy programming,” resulting in a relatively balanced use of ones and zeros. Healthy programming refers to fair programming, where any cell has an equal likelihood of being programmed to any of the cell levels. Only pages where all the cells are programmed (instead of being erased) will prevent discharging of the bitline—all cases where at least one zero is stored in a cell will result in the bitline discharging.

In the case of SLC (single level cell) mode, the cells are binary, storing either a one or a zero. Thus, fair pattern programming indicates that the probability of a zero is approximately the same as the probability of a one. Thus, P[‘0’]˜P[‘1’]˜0.5. In a multilevel cell mode, the cells will be programmed at more levels, and the statistical information related to zeros and ones may be more challenging for accurate characterization of a storage device.

Knowing that any erased cells will discharge the bitlines, the program verify can include application of a verify read pulse to multiple subblocks simultaneously, counting a number of bitlines of the multiple subblocks that do not discharge in response to the verify read pulse. The program verify passes if the count is within an expected range, instead of requiring all storage cells to pass program verify before moving on. If the number of bitlines not discharging is outside the expected range, the system can optionally perform a second program pass or optionally report a status fail.

By performing verify on multiple subblocks simultaneously, for example, on M subblocks, the cost of verify is divided by M. Consider a system having 16 total subblocks, where verify is performed on 6 subblocks, the cost of the verify is divided by M=6. The system can verify 4, 5, 6, 7, or 8 pages in parallel. Improvements in SLC programming time have been observed of approximately 30% over traditional SLC programming, without compromising the quality.

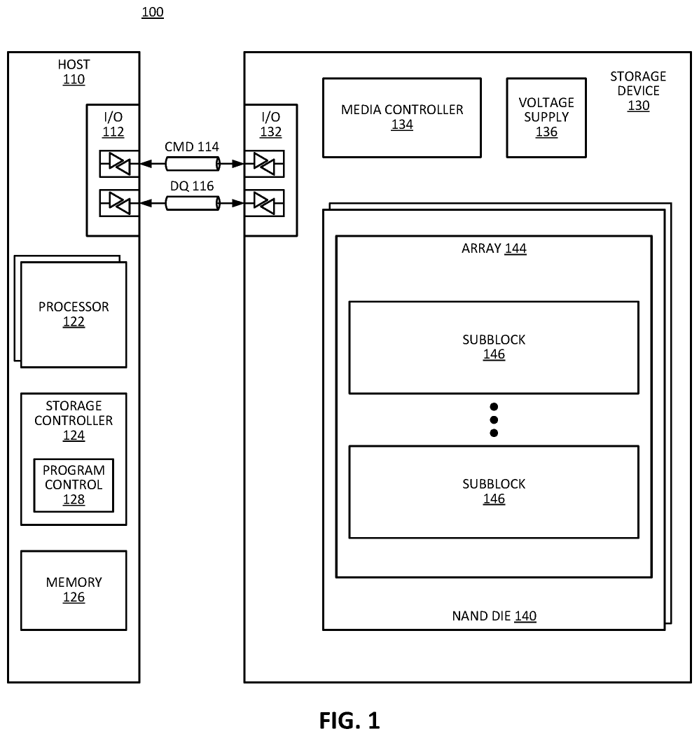

FIG. 1 is a block diagram of an example of a system with a storage device having multiple decks. System 100 includes host 110, which represents the host system to which storage device 130 is connected. Storage device 130 provides a storage resource to store data for host 110.

Host 110 includes processor 122, storage controller 124, and memory 126. Processor 122 represents a host processor or computing device for host 110, which can be a single core device or a multicore device. Storage controller 124 represents a controller in host 110 that manages access to storage device 130. Storage controller 124 can perform scheduling and manage timing and data transfer with storage device 130. In one example, storage controller 124 includes program control 128, which enables storage controller 124 to perform program verify on multiple subblocks simultaneously.

Memory 126 represents operational memory in host 110. The operational memory is typically volatile memory, which has indeterminate state if power is interrupted to the memory. The operational memory could alternatively be nonvolatile memory, which has determinate state even when power is interrupted to the memory. Memory 126 generally holds data and code for use by processor 122. Data read from storage device 130 is typically stored in memory 126 for use by processor 122.

Host 110 includes I/O (input/output) 112, which represents hardware to interface with an external device, such as storage device 130, which can represent a peripheral device. I/O 132 represents hardware of storage device 130 to interface with host 110 through I/O 112. In one example, the interconnection between I/O 112 and I/O 132 can include a command connection or command link or command bus, as represented by CMD (command) 114. The link/bus can be signal lines over which host 110 sends commands to storage device 130. The interconnection can include a data bus represented by DQ (data) 116.

Storage device 130 includes media controller 134, which represents a controller on the storage device to manage the NVM (nonvolatile memory) resources. Media controller 134 receives commands from storage controller 124 and decodes and executes the commands. Media controller 134 can send control signals to array 144 to implement program and read operations.

As illustrated, storage device 130 includes multiple NAND dies 140. In one example, NAND dies 140 include array 144. Array 144 can be a multilevel storage device, such as MLC (multilevel cell), TLC (triple level cell), QLC (quad level cell), or other encoding scheme.

Array 144 includes N wordlines (WL[0] to WL[N-1]). Access to the columns, pillars or strings of the storage cells can be addressed by row (wordline or WL) address and column (bitline or BL) address, and gated with control gate signals. In one example, the array is organized as multiple subblocks 146. Subblocks 146 can be accessed separately from each other. Unlike other systems, system 100 enables program verify of multiple subblocks simultaneously.

In one example, array 144 includes multiple vertical stacks, with a stack corresponding to each bitline (e.g., BL[0], BL[1], . . . ). The vertical stack includes a vertical channel passing through the various wordlines, with the channel controlled by control gate signals. The control gate signals can be referred to as switching signals that provide gating control for a channel. The control signals can enable access to different subblocks simultaneously for program verify.

In one example, array 144 has an SLC mode and a mode for storing multiple bits per cell. In a typical SLC system, media controller 134 can perform program verify on SLC by implementing a program verify algorithm. The algorithm can sample the starting pulse on the first page of any given array region (e.g., WL (wordline) group), and for the rest of the pages (e.g., approximately 99%, non-sampling pages), the algorithm programs in a single loop with one pulse and one verify (1P1V).

Voltage supply 136 represents a power supply in storage device 130. Voltage supply 136 can be or include a voltage regulator to provide power to the circuits to enable access to storage cells of array 144.

Media controller 134 can perform operations based on NAND trims stored in storage device 130. The NAND trims are typically calibrated to maintain 100% non-sampling single loop due to the need for fast programming speed. In single loop operation, the verify is primarily used as a quality check and to is used to report the programming status (pass or fail) for the solid-state drive.

Instead of removing the verify completely removing program verify, system 100 can perform verify based on statistical heuristics. The verify based on statistics can include a precomputation based on a statistical analysis of how many bitlines or bytes would be counted assuming healthy programming. Reliability and verification of solid state drives is based on the assumption of the use of random writes, providing, on average, a 50/50 chance of ones to zeros.

Since a bitline connects to multiple subblocks, if any of the cells are erased in any of the subblocks, the bitline will discharge. For example, if 6 channels are connected to a bitline, any erased cells of those channels will discharge the bitline. Only when all cells for the channels are programmed with the bitline not discharge.

In one example, media controller 134 performs verify on multiple subblocks simultaneously, say M subblocks. Applying verify to M subblocks in parallel reduces the effective verify time (1/M), while maintaining the quality of verify and meaningful program status reporting to the SSD (solid state drive) without elongating the verify waveform or making the algorithm much more complicated.

Accordingly, media controller 134 can count cases of “did not discharge” instead of counting cases of discharge, as traditionally done. Instead of counting the bitlines that discharge in response to a verify read pulse to determine a pass or fail for verify, the system can count the number of bitlines that do not discharge in response to the verify pulse, and determine if the number is within an expected range for random writes. It will be understood that different media and different process variations may cause some differences in the expected range. However, the expected range can be set for different systems and then applied to enable program verify of multiple subblocks simultaneously.

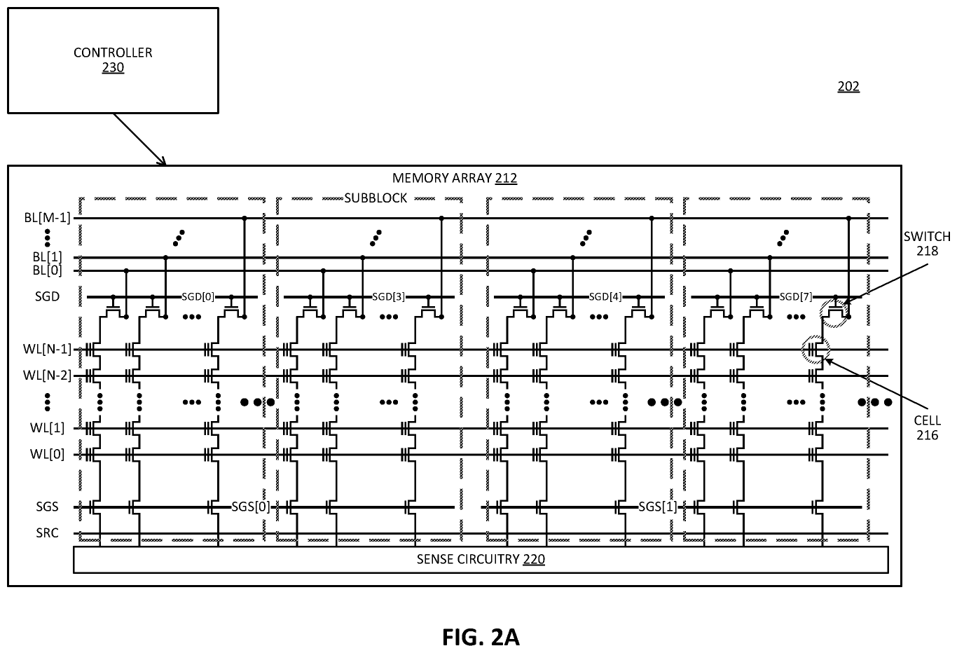

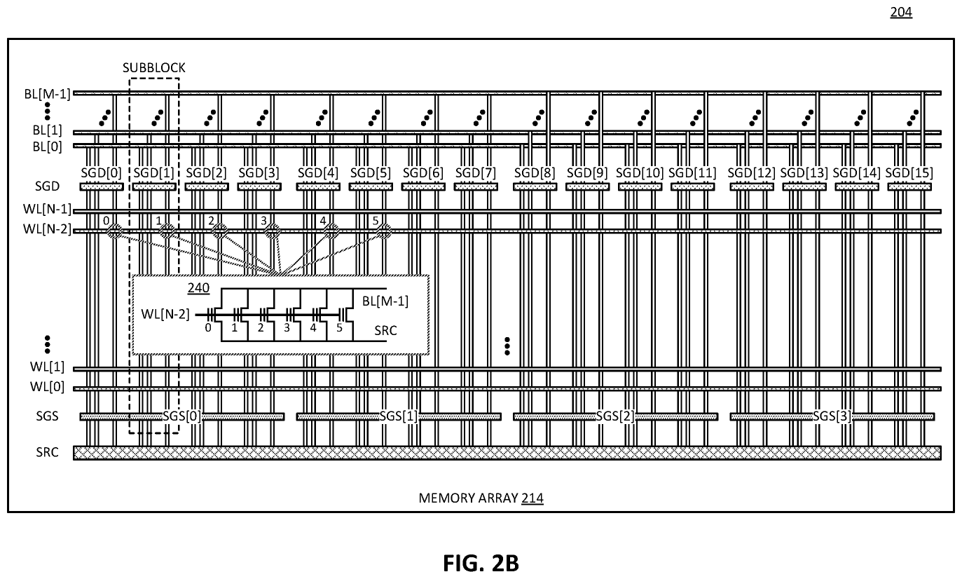

FIG. 2A is a block diagram of an example of a system having a storage array in which multideck program verify can be implemented. System 202 represents a storage device in which a deck reset read can be implemented. System 202 can be, or be included in, an SSD (solid state drive). System 202 can be integrated into a computing device.

System 202 includes memory array 212, which represents a 3D NAND storage device, with multiple decks of stacked wordlines. In one example, cells 216 represent NAND storage cells. In one example, cells 216 represent NOR-based storage cells. Memory array 212 includes N wordlines (WL[0] to WL[N-1]).

In one example, memory array 212 is segmented into subblocks. A block of cells refers to cells coupled to the same SGS, with SGS[0] and SGS[1] illustrated. A subblock of cells refers to cells coupled to the same SGD, with SGD[0], SGD[1], SGD[7] illustrated. The separation with source and drain portions are only to be understood as illustrative and not limiting.

In one example, a subblock refers to the columns, pillars, or strings of storage cells 216 that are accessed together. The pillars can be accessed together by responding to a common switching signal. The switching signal can refer to gating control for the pillar. Switch 218 represents the gating control for the pillar. An SGD signal line selectively couples a column pillar to a BL (bitline). An SGS signal line selectively couples a column to a source (SRC), which is a source plane. The source can alternatively be referred to as an SL (source layer), which is a source layer of material integrated onto a semiconductor substrate.

One bitline is coupled to different subblocks. Each subblock can be coupled to M bitlines (BL[0] to BL[M-1]). In one example, each storage cell 216 within memory array 212 is addressed or selected by asserting a wordline and a bitline, in conjunction with enabling the column with the gate select switches 218 (shown only on SGD, but SGS switches can be considered included in the control). System 202 illustrates sense circuitry 220, which represents the circuitry to stage data for reads and writes. In one example, sense circuitry 220 can represent the SPB (static page buffer). The SPB can include latch circuitry, including an InH latch to count cells that do not discharge, or are inhibited from discharging.

In one example, system 202 includes controller 230 to apply verify of multiple subblocks simultaneously in accordance with any example described. Controller 230 can represent an example of a media controller that manages the program verify for memory array 212. As described herein, the verify of multiple subblocks together is based on determining if a number of bitlines are not discharged in response to the verify pulse.

FIG. 2B is a block diagram of an example of a circuit structure for the system of FIG. 2A. System 204 provides an example structure to implement a system in accordance with system 202 of FIG. 2A. System 204 illustrates circuit details for SGD[0], SGD[1], and SGS[0]. The source layer is common to all the subblocks, as are the wordlines (WL[0] to WL[N-1]). In one example, cell 216 is formed at an intersection of a wordline and a bitline. In one example, switch 218 is formed at an intersection of a select line a bitline.

System 204 illustrates memory array 214 with 16 subblocks, but a system can be made with more or fewer subblocks. Each subblock is separately accessed through the drain side select gate (SGD[0:15]). System 204 includes an inset, illustrated as diagram 240, which is a circuit representation of the storage cells of WL[N-2] for subblocks 0:5 (SGD[0:5]) at BL[M-1]. The storage cells are labeled 0, 1, 2, 3, 4, 5 for illustration. Consider that these six subblocks would be verified simultaneously.

In system 204, in one example, the media controller will turn on SGD[0:5] simultaneously while verifying in SLC. With SGD[0:5] turned on, the six adjacent subblocks will be conductive, and the six storage cells can be sensed together. In one example, all bitlines are sensed, and there is no targeted bitline verify. The verify will be counted (e.g., InH latch trigger) if and only if all the connected cells are programmed, which is a minority event given fair, random pattern programming. In one example, if at least one of the cells is erased, the SPB will behave like a verify fail and the InH latch will not flip. A pass will happen only if all the cells connected to the bitline are programmed.

While system 204 illustrates six subblocks to be verified in parallel, the simultaneous verify can be 4, 5, 6, 7, or 8 subblocks, or some other number of subblocks. The number of subblocks verified in parallel can be portion/subset of the total number of subblocks in the system. System 204 illustrates such an example, with the 6 subblocks being a portion of the 16 total subblocks. With a small number of subblocks, the system could potentially verify all subblocks in parallel.

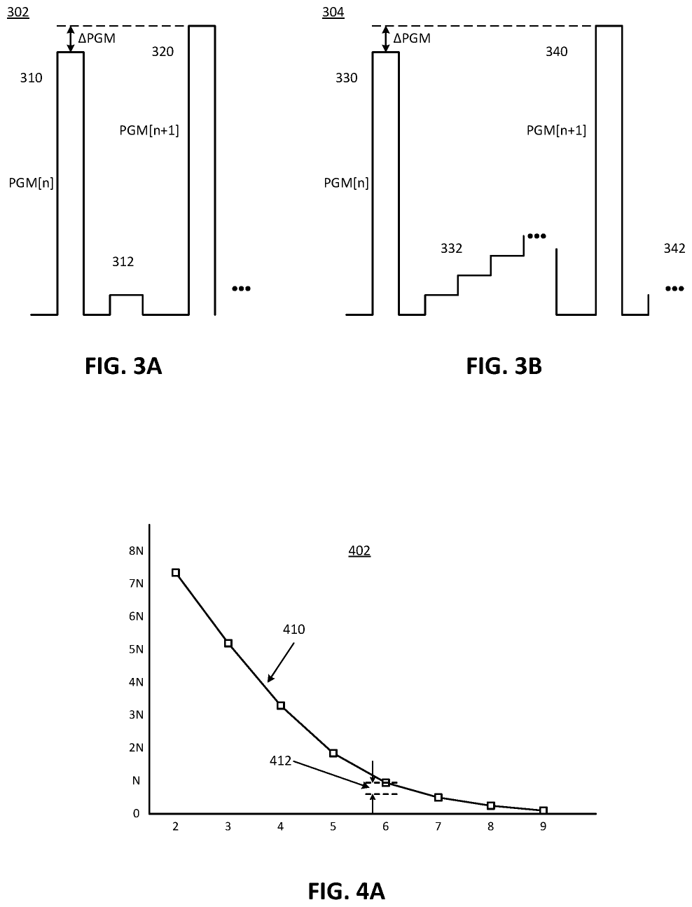

FIG. 3A is a plot of an example of program verify for an SLC cell. Diagram 302 represents an example of a program waveform for a single bit cell. For program, the system applies program pulse 310 (the first program pulse, PGM[n]) of amplitude of V_{PGM}, followed by verify operation at 312. In one example, for cells determined to not pass, the system can increase the program pulse by ΔV_{PGM} and apply program pulse 320 (the second program pulse, PGM[n+1] with the higher amplitude, followed by verify operation.

In one example, as described herein, the system can perform verify once at 312, count the number of bitlines that did not discharge for multiple subblocks in parallel, and determine if the number of bitlines that did not discharge is within an expected range. In one example, the system can either log the failure, or can apply the second program pulse.

FIG. 3B is a plot of an example of program verify for an SLC cell. Diagram 304 represents an example of a program waveform for a multibit cell. For program, the system applies program pulse 330 (the first program pulse, PGM[n]) of amplitude of V_{PGM}, followed by verify operation at 332, performing a sequence of increase verify pulse to check the different voltage levels of the cell. For cells determined to not pass, the system can increase the program pulse by ΔV_{PGM} and apply program pulse 340 (the second program pulse, PGM[n+1] with the higher amplitude, followed by verify operation at 342.

While the program and verify operation is illustrated for a multibit cell, in one example, the program verify described herein is not applied to multibit cells.

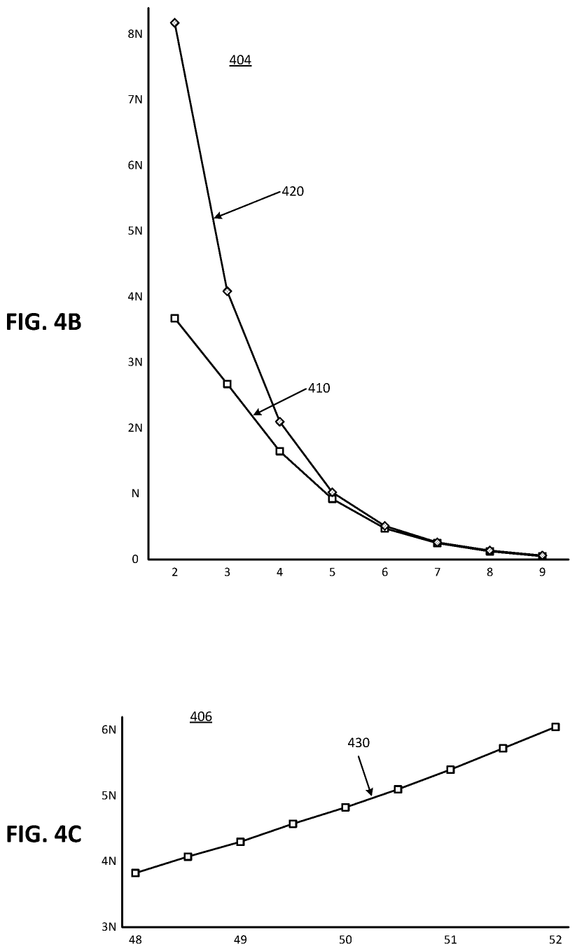

FIG. 4A is a diagram representing byte pass rates for multiple subblocks verified simultaneously. Diagram 402 illustrates the number of passing bytes for a selected number of bytes (vertical axis), plotted against the number of subblocks verified as a group (horizontal axis). Diagram 402 illustrates a representation of the number of passing bytes generically, rather than using specific numbers. N can be, for example, 500 or 100. It will be understood that the plot for different devices is expected to have a similar shape, although the specific numbers could be different, which is why the specific numbers are not shown in diagram 402.

Diagram 402 is based on verify as described herein, which counts passes instead of counting fails like a normal verify. The statistical model for the appropriate criterion to decide on passing the status of failing m subblocks verified in parallel can be:

$$1 - {( 1 - {( {P}_{1} )}^{m} )}^{8} = \frac{{N}_{passing \_ B}}{{N}_{sample \_ B}}$$

In the equation, P₁=ratio of Level1 cells [pattern randomness]=0.5.

P_{b}=probability (ratio) of bitlines passing a given verify pass and resulting in an INH latch trigger.

P_{b}=(P₁)^{m}, data in the m adjacent subblocks are random and independent.

P_{B}=probability (ratio) of bytes passing the criterion. A byte will pass if at least one bitline passes in the that byte.

P_{B}=1−(1−P_{b})⁸, indicating that a byte will fail only if all the bits there are failing.

The count fail circuit can be either byte based or bit based. Consider a case where a count is based on 4090 bytes of bitlines, which give N_{sample_B}=4090 bytes and N_{sample_b}=32720 bitlines.

The system can calculate the expected number of bytes and bitlines to pass in a healthy sample by: N_{passing_B}=P_{B}*N_{sample_B} and N_{passing_b}=P_{b}*N_{sample_b}

Based on the above statistical model, the number of expected bitlines to pass (or bytes) can be calculated for any number (m) assuming healthy programming.

Curve 410 is characteristic of the expected number of passing bytes for multi-subblock verify. The mark at 412 indicates an example of m=6 subblocks, where the threshold of passing is at least the box point on curve 410. The dashed lines indicate an example where the system is configured to accept a pass rate within a range. The range can be referred to as a failure tail or error tail, where the failure can be accepted based on an acceptable failure rate. Thus, the tail can be used to indicate an acceptable error tail for passing verify. In one example, a failure range can be accepted in a system that applies ECC (error checking and correction) or other error correction.

FIG. 4B is a diagram representing byte and bitline pass rates for multiple subblocks verified simultaneously. Diagram 404 illustrates pass rates in accordance with an example of diagram 402. More specifically, diagram 404 plots both the byte passing rate, curve 410 of diagram 402, and the bitline passing rate, curve 420. As with curve 410, curve 420 can be calibrated with a threshold number that is higher or lower than what is illustrated to allow for minor acceptable tails.

FIG. 4C is a diagram representing the percentage of L1 (level 1) cells for multiple subblocks verified simultaneously. Diagram 406 illustrates the sensitivity of the passing criterion threshold to the percentage of cells that is supposed to be programmed for the number of subblocks verified in parallel.

As with diagram 402 and diagram 404, diagram 406 illustrates the number of passing bytes for a selected number of bytes (vertical axis) without showing the specific numbers. Rather, curve 430 is a characteristic curve. N can be, for example, 500 or 100. It will be understood that the plot for different devices is expected to have a similar shape, although the specific numbers could be different, which is why the specific numbers are not shown in diagram 406.

Curve 430 more specifically illustrates a characteristic response for a case of m=6 subblocks. Diagram 406 represents the fact that a lower placement tail will recue the observed count of passing since it becomes rarer to find a bitline that is connected to all cells with higher threshold voltage. The sensitivity to the probability of having programmed bits can guide the amount of relaxation needed in the passing criterion threshold based on acceptable tails in the manufactured product. For example, consider that curve 430 has a slope of 55 bytes for every 1%. If a 1% tail is permitted, the acceptable threshold can be reduced by 55 bytes.

In all cases where a tail is permitted, the system can allow some errors intentionally. Intentionally allowing errors can improve program performance by permitting programming to happen more quickly. With error correction in systems, the errors allowed in the system should not have an appreciable effect on the read performance.

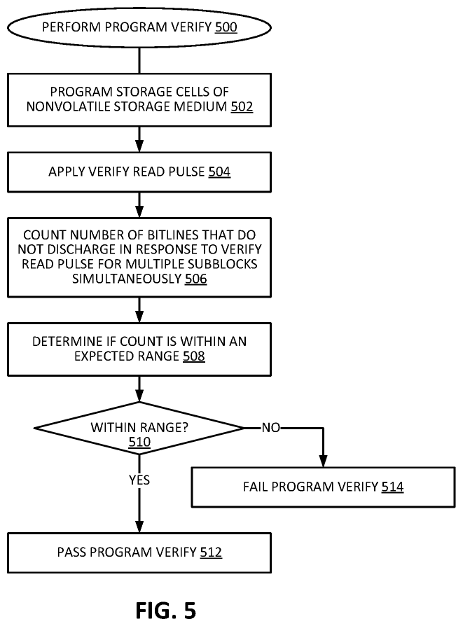

FIG. 5 is a flow diagram of a process for multideck program verify. Process 500 represents a process for performing program verify in accordance with an example of a system described above.

The system programs the storage cells of a nonvolatile storage medium, at 502. After the program operation, the system applies a verify read pulse to verify the programming, at 504. In one example, the system counts the number of bitlines or the number of bytes with bitlines that do not discharge in response to the verify read pulse for multiple subblocks simultaneously, at 506.

The system can determine if the count (either a count of bitlines or the count of bytes) is within an expected range, at 508. If the count is not within the range, at 510 NO branch, the system can fail the program verify, at 514. The system determine to perform another program and verify operation, or can report the error.

If the count is within the range, at 510 YES branch, the system can pass the program verify, at 512. In one example, the range is a threshold number. In one example, the threshold number is adjusted based on an acceptable tail.

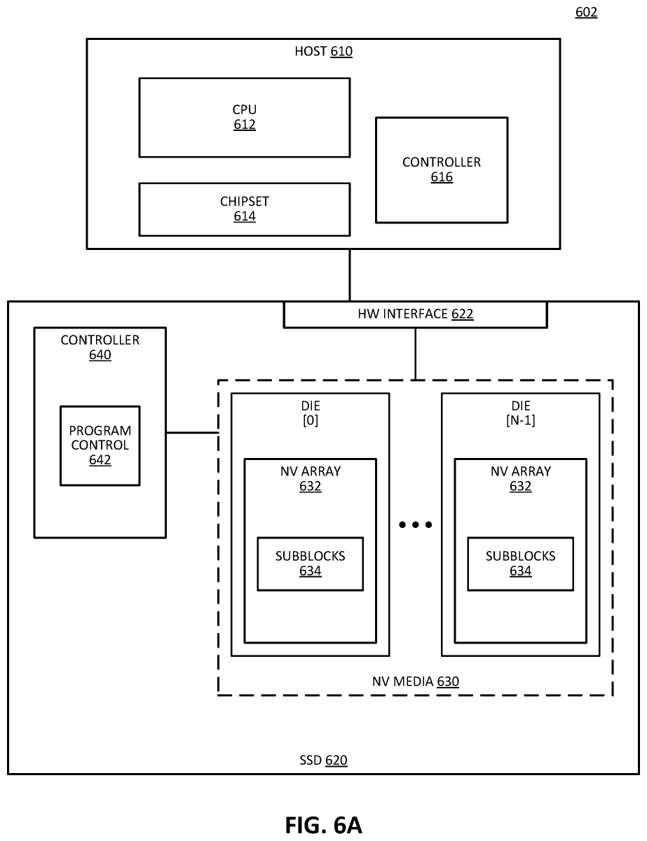

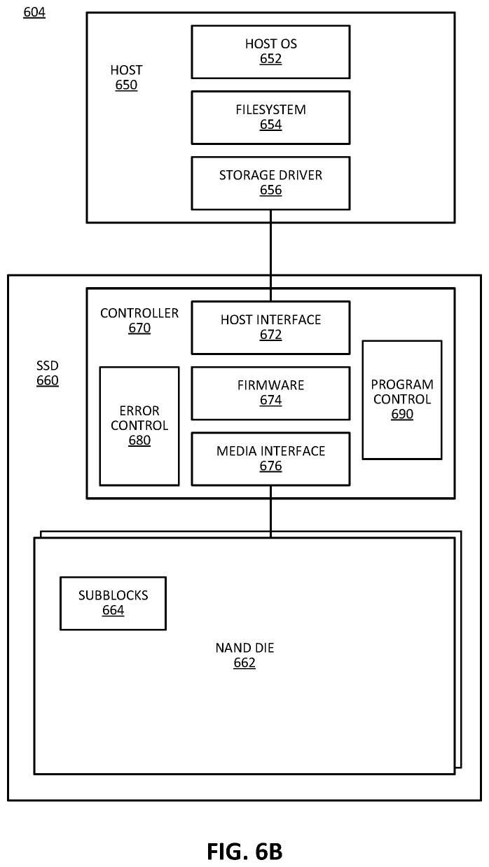

FIG. 6A is a block diagram of an example of a system with a solid state drive (SSD) in which multideck program verify can be implemented. System 602 represents components of a storage system in accordance with an example of system 100, system 202, or system 204. System 602 can be a 3D NAND storage device that supports verify of multiple subblocks simultaneously, in accordance with any example herein.

System 602 includes host 610 coupled to SSD 620. Host 610 represents a host hardware platform that connects to SSD 620. Host 610 includes CPU (central processing unit) 612 or other processor as a host processor or host processor device. CPU 612 represents any host processor that generates requests to access data stored on SSD 620, either to read the data or to write data to the storage. Such a processor can include a single or multicore processor, a primary processor for a computing device, a graphics processor, a peripheral processor, or a supplemental or auxiliary processor, or a combination. CPU 612 can execute a host OS and other applications to cause the operation of system 602.

Host 610 includes chipset 614, which represents hardware components such as interconnect circuits and logic to enable access to SSD 620. Host 610 includes controller 616, which represents a storage controller or memory controller on the host side to control access to SSD 620. In one example, controller 616 is included in chipset 614. In one example, controller 616 is included in CPU 612. Controller 616 can be referred to as an NV memory controller or storage controller to enable host 610 to schedule and organize commands to SSD 620 to read and write data.

SSD 620 represents a solid-state drive or other storage system or module that includes NV (nonvolatile) media 630 to store data. NV media 630 can be, for example, a 3D NAND array. SSD 620 includes HW (hardware) interface 622, which represents hardware components to interface with host 610. For example, HW interface 622 can interface with one or more buses to implement a high speed interface standard such as NVMe (nonvolatile memory express) or PCIe (peripheral component interconnect express).

In one example, NV media 630 is implemented as multiple dies, illustrated as N dies, Die[0:(N-1)]. N can be any number of devices, and is often a binary number. SSD 620 includes controller 640 to control access to NV media 630. Controller 640 represents hardware and control logic within SSD 620 to execute control over the media. Controller 640 is internal to the nonvolatile storage device or module, and is separate from controller 616 of host 610.

The NV dies of NV media 630 include 3D NV array 632, which is a three-dimensional array of storage cells based on the NV media. In one example, NV array 632 includes subblocks 634. In one example, controller 640 includes program control 642 to implement verify on multiple subblocks in parallel, in accordance with any example herein.

FIG. 6B is a block diagram of an example of a system with a solid state drive (SSD) with a controller to manage multideck program verify. System 604 provides one example of a system in accordance with system 602 of FIG. 6A. System 604 can represent software and firmware components of an example of system 602, as well as physical components. In one example, host 650 provides one example of host 610. In one example, SSD 660 provides one example of SSD 620.

In one example, host 650 includes host OS 652, which represents a host operating system or software platform for the host. Host OS 652 can include a platform on which applications, services, agents, and/or other software executes, and is executed by a processor. Filesystem 654 represents control logic for controlling access to the NV media. Filesystem 654 can manage what addresses or memory locations are used to store what data. There are numerous filesystems known, and filesystem 654 can implement known filesystems or other proprietary systems. In one example, filesystem 654 is part of host OS 652.

Storage driver 656 represents one or more system-level modules that control the hardware of host 650. In one example, drivers 656 include a software application to control the interface to SSD 660, and thus control the hardware of SSD 660. Storage driver 656 can provide a communication interface between the host and the SSD.

Controller 670 of SSD 660 includes firmware 674, which represents control software/firmware for the controller. In one example, controller 670 includes host interface 672, which represents an interface to host 650. In one example, controller 670 includes media interface 676, which represents an interface to NAND die 662. NAND die 662 represents a specific example of NV media, and includes an associated 3D NAND array.

Media interface 676 represents control that is executed on hardware of controller 670. It will be understood that controller 670 includes hardware to interface with host 650, which can be considered to be controlled by host interface software/firmware 674. Likewise, it will be understood that controller 670 includes hardware to interface with NAND die 662. In one example, code for host interface 672 can be part of firmware 674. In one example, code for media interface 676 can be part of firmware 674.

In one example, controller 670 includes error control 680 to handle data errors in accessed data, and corner cases in terms of compliance with signaling and communication interfacing. Error control 680 can include implementations in hardware or firmware, or a combination of hardware and software.

In one example, NAND die 662 has subblocks 664. In one example, system 604 includes program control 690 to implement verify on multiple subblocks in parallel, in accordance with any example herein.

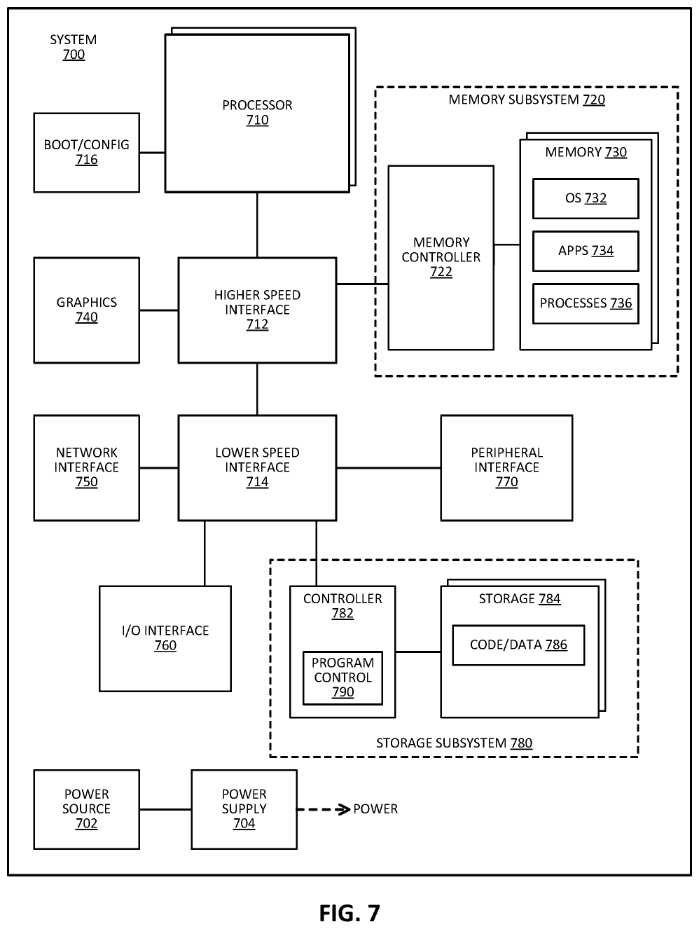

FIG. 7 is a block diagram of an example of a computing system in which multideck program verify can be implemented. System 700 represents a computing device in accordance with any example herein, and can be a laptop computer, a desktop computer, a tablet computer, a server, a gaming or entertainment control system, embedded computing device, or other electronic device.

System 700 represents a system with storage in accordance with an example of system 100 or system 202 or system 204. In one example, controller 782 includes program control 790. Program control 790 enables system 700 to implement verify on multiple subblocks of storage 784 simultaneously, in accordance with any example herein.

System 700 includes processor 710 can include any type of microprocessor, central processing unit (CPU), graphics processing unit (GPU), processing core, or other processing hardware, or a combination, to provide processing or execution of instructions for system 700. Processor 710 can be a host processor device. Processor 710 controls the overall operation of system 700, and can be or include, one or more programmable general-purpose or special-purpose microprocessors, digital signal processors (DSPs), programmable controllers, application specific integrated circuits (ASICs), programmable logic devices (PLDs), or a combination of such devices.

System 700 includes boot/config 716, which represents storage to store boot code (e.g., basic input/output system (BIOS)), configuration settings, security hardware (e.g., trusted platform module (TPM)), or other system level hardware that operates outside of a host OS. Boot/config 716 can include a nonvolatile storage device, such as read-only memory (ROM), flash memory, or other memory devices.

In one example, system 700 includes interface 712 coupled to processor 710, which can represent a higher speed interface or a high throughput interface for system components that need higher bandwidth connections, such as memory subsystem 720 or graphics interface components 740. Interface 712 represents an interface circuit, which can be a standalone component or integrated onto a processor die. Interface 712 can be integrated as a circuit onto the processor die or integrated as a component on a system on a chip. Where present, graphics interface 740 interfaces to graphics components for providing a visual display to a user of system 700. Graphics interface 740 can be a standalone component or integrated onto the processor die or system on a chip. In one example, graphics interface 740 can drive a high definition (HD) display or ultra high definition (UHD) display that provides an output to a user. In one example, the display can include a touchscreen display. In one example, graphics interface 740 generates a display based on data stored in memory 730 or based on operations executed by processor 710 or both.

Memory subsystem 720 represents the main memory of system 700, and provides storage for code to be executed by processor 710, or data values to be used in executing a routine. Memory subsystem 720 can include one or more varieties of random-access memory (RAM) such as DRAM, 3DXP (three-dimensional crosspoint), or other memory devices, or a combination of such devices. Memory 730 stores and hosts, among other things, operating system (OS) 732 to provide a software platform for execution of instructions in system 700. Additionally, applications 734 can execute on the software platform of OS 732 from memory 730. Applications 734 represent programs that have their own operational logic to perform execution of one or more functions. Processes 736 represent agents or routines that provide auxiliary functions to OS 732 or one or more applications 734 or a combination. OS 732, applications 734, and processes 736 provide software logic to provide functions for system 700. In one example, memory subsystem 720 includes memory controller 722, which is a memory controller to generate and issue commands to memory 730. It will be understood that memory controller 722 could be a physical part of processor 710 or a physical part of interface 712. For example, memory controller 722 can be an integrated memory controller, integrated onto a circuit with processor 710, such as integrated onto the processor die or a system on a chip.

While not specifically illustrated, it will be understood that system 700 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a HyperTransport or industry standard architecture (ISA) bus, a small computer system interface (SCSI) bus, a universal serial bus (USB), or other bus, or a combination.

In one example, system 700 includes interface 714, which can be coupled to interface 712. Interface 714 can be a lower speed interface than interface 712. In one example, interface 714 represents an interface circuit, which can include standalone components and integrated circuitry. In one example, multiple user interface components or peripheral components, or both, couple to interface 714. Network interface 750 provides system 700 the ability to communicate with remote devices (e.g., servers or other computing devices) over one or more networks. Network interface 750 can include an Ethernet adapter, wireless interconnection components, cellular network interconnection components, USB (universal serial bus), or other wired or wireless standards-based or proprietary network interface circuit. Network interface 750 can exchange data with a remote device, which can include sending data stored in memory or receiving data to be stored in memory.

In one example, system 700 includes one or more input/output (I/O) interface(s) 760. I/O interface 760 can include one or more interface components through which a user interacts with system 700 (e.g., audio, alphanumeric, tactile/touch, or other interfacing). Peripheral interface 770 can include any hardware interface not specifically mentioned above. Peripherals refer generally to devices that connect dependently to system 700. A dependent connection is one where system 700 provides the software platform or hardware platform or both on which operation executes, and with which a user interacts.

In one example, system 700 includes storage subsystem 780 to store data in a nonvolatile manner. In one example, in certain system implementations, at least certain components of storage 780 can overlap with components of memory subsystem 720. Storage subsystem 780 includes storage device(s) 784, which can be or include any conventional medium for storing large amounts of data in a nonvolatile manner, such as one or more magnetic, solid state, NAND, 3DXP, or optical based disks, or a combination. Storage 784 holds code or instructions and data 786 in a persistent state (i.e., the value is retained despite interruption of power to system 700). Storage 784 can be generically considered to be a “memory,” although memory 730 is typically the executing or operating memory to provide instructions to processor 710. Whereas storage 784 is nonvolatile, memory 730 can include volatile memory (i.e., the value or state of the data is indeterminate if power is interrupted to system 700). In one example, storage subsystem 780 includes controller 782 to interface with storage 784. In one example controller 782 is a physical part of interface 714 or processor 710, or can include circuits or logic in both processor 710 and interface 714.

Power source 702 provides power to the components of system 700. More specifically, power source 702 typically interfaces to one or multiple power supplies 704 in system 700 to provide power to the components of system 700. In one example, power supply 704 includes an AC to DC (alternating current to direct current) adapter to plug into a wall outlet. Such AC power can be renewable energy (e.g., solar power) power source 702. In one example, power source 702 includes a DC power source, such as an external AC to DC converter. In one example, power source 702 or power supply 704 includes wireless charging hardware to charge via proximity to a charging field. In one example, power source 702 can include an internal battery or fuel cell source.

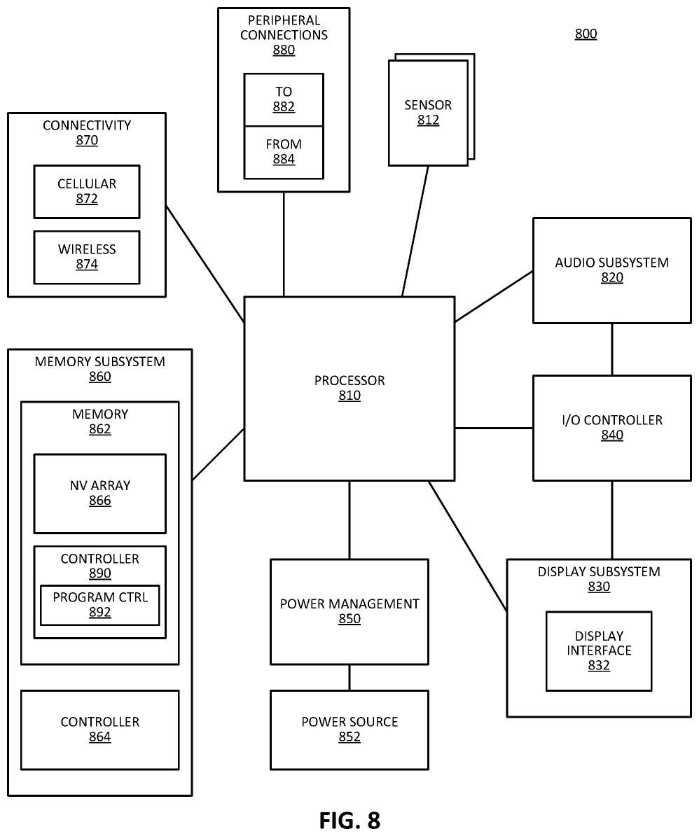

FIG. 8 is a block diagram of an example of a mobile device in which multideck program verify can be implemented. System 800 represents a mobile computing device, such as a computing tablet, a mobile phone or smartphone, wearable computing device, or other mobile device, or an embedded computing device. It will be understood that certain of the components are shown generally, and not all components of such a device are shown in system 800.

System 800 represents a system with storage in accordance with an example of system 100 or system 202 or system 204. Memory 862 includes NV (nonvolatile) array 866 to store data. In one example, controller 890 includes program control (CTRL) 892. Program control 892 enables system 800 to implement verify on multiple subblocks of NV array 866 simultaneously, in accordance with any example herein.

System 800 includes processor 810, which performs the primary processing operations of system 800. Processor 810 can be a host processor device. Processor 810 can include one or more physical devices, such as microprocessors, application processors, microcontrollers, programmable logic devices, or other processing means. The processing operations performed by processor 810 include the execution of an operating platform or operating system on which applications and device functions are executed. The processing operations include operations related to I/O (input/output) with a human user or with other devices, operations related to power management, operations related to connecting system 800 to another device, or a combination. The processing operations can also include operations related to audio I/O, display I/O, or other interfacing, or a combination. Processor 810 can execute data stored in memory. Processor 810 can write or edit data stored in memory.

In one example, system 800 includes one or more sensors 812. Sensors 812 represent embedded sensors or interfaces to external sensors, or a combination. Sensors 812 enable system 800 to monitor or detect one or more conditions of an environment or a device in which system 800 is implemented. Sensors 812 can include environmental sensors (such as temperature sensors, motion detectors, light detectors, cameras, chemical sensors (e.g., carbon monoxide, carbon dioxide, or other chemical sensors)), pressure sensors, accelerometers, gyroscopes, medical or physiology sensors (e.g., biosensors, heart rate monitors, or other sensors to detect physiological attributes), or other sensors, or a combination. Sensors 812 can also include sensors for biometric systems such as fingerprint recognition systems, face detection or recognition systems, or other systems that detect or recognize user features. Sensors 812 should be understood broadly, and not limiting on the many different types of sensors that could be implemented with system 800. In one example, one or more sensors 812 couples to processor 810 via a frontend circuit integrated with processor 810. In one example, one or more sensors 812 couples to processor 810 via another component of system 800.

In one example, system 800 includes audio subsystem 820, which represents hardware (e.g., audio hardware and audio circuits) and software (e.g., drivers, codecs) components associated with providing audio functions to the computing device. Audio functions can include speaker or headphone output, as well as microphone input. Devices for such functions can be integrated into system 800, or connected to system 800. In one example, a user interacts with system 800 by providing audio commands that are received and processed by processor 810.

Display subsystem 830 represents hardware (e.g., display devices) and software components (e.g., drivers) that provide a visual display for presentation to a user. In one example, the display includes tactile components or touchscreen elements for a user to interact with the computing device. Display subsystem 830 includes display interface 832, which includes the particular screen or hardware device used to provide a display to a user. In one example, display interface 832 includes logic separate from processor 810 (such as a graphics processor) to perform at least some processing related to the display. In one example, display subsystem 830 includes a touchscreen device that provides both output and input to a user. In one example, display subsystem 830 includes a high definition (HD) or ultra-high definition (UHD) display that provides an output to a user. In one example, display subsystem includes or drives a touchscreen display. In one example, display subsystem 830 generates display information based on data stored in memory or based on operations executed by processor 810 or both.

I/O controller 840 represents hardware devices and software components related to interaction with a user. I/O controller 840 can operate to manage hardware that is part of audio subsystem 820, or display subsystem 830, or both. Additionally, I/O controller 840 illustrates a connection point for additional devices that connect to system 800 through which a user might interact with the system. For example, devices that can be attached to system 800 might include microphone devices, speaker or stereo systems, video systems or other display device, keyboard or keypad devices, buttons/switches, or other I/O devices for use with specific applications such as card readers or other devices.

As mentioned above, I/O controller 840 can interact with audio subsystem 820 or display subsystem 830 or both. For example, input through a microphone or other audio device can provide input or commands for one or more applications or functions of system 800. Additionally, audio output can be provided instead of or in addition to display output. In another example, if display subsystem includes a touchscreen, the display device also acts as an input device, which can be at least partially managed by I/O controller 840. There can also be additional buttons or switches on system 800 to provide I/O functions managed by I/O controller 840.

In one example, I/O controller 840 manages devices such as accelerometers, cameras, light sensors or other environmental sensors, gyroscopes, global positioning system (GPS), or other hardware that can be included in system 800, or sensors 812. The input can be part of direct user interaction, as well as providing environmental input to the system to influence its operations (such as filtering for noise, adjusting displays for brightness detection, applying a flash for a camera, or other features).

In one example, system 800 includes power management 850 that manages battery power usage, charging of the battery, and features related to power saving operation. Power management 850 manages power from power source 852, which provides power to the components of system 800. In one example, power source 852 includes an AC to DC (alternating current to direct current) adapter to plug into a wall outlet. Such AC power can be renewable energy (e.g., solar power, motion based power). In one example, power source 852 includes only DC power, which can be provided by a DC power source, such as an external AC to DC converter. In one example, power source 852 includes wireless charging hardware to charge via proximity to a charging field. In one example, power source 852 can include an internal battery or fuel cell source.

Memory subsystem 860 includes memory device(s) 862 for storing information in system 800. Memory subsystem 860 can include nonvolatile (state does not change if power to the memory device is interrupted) or volatile (state is indeterminate if power to the memory device is interrupted) memory devices, or a combination. Memory 860 can store application data, user data, music, photos, documents, or other data, as well as system data (whether long-term or temporary) related to the execution of the applications and functions of system 800. In one example, memory subsystem 860 includes memory controller 864 (which could also be considered part of the control of system 800, and could potentially be considered part of processor 810). Memory controller 864 includes a scheduler to generate and issue commands to control access to memory device 862.

Connectivity 870 includes hardware devices (e.g., wireless or wired connectors and communication hardware, or a combination of wired and wireless hardware) and software components (e.g., drivers, protocol stacks) to enable system 800 to communicate with external devices. The external device could be separate devices, such as other computing devices, wireless access points or base stations, as well as peripherals such as headsets, printers, or other devices. In one example, system 800 exchanges data with an external device for storage in memory or for display on a display device. The exchanged data can include data to be stored in memory, or data already stored in memory, to read, write, or edit data.

Connectivity 870 can include multiple different types of connectivity. To generalize, system 800 is illustrated with cellular connectivity 872 and wireless connectivity 874. Cellular connectivity 872 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, LTE (long term evolution—also referred to as “4G”), 5G, or other cellular service standards. Wireless connectivity 874 refers to wireless connectivity that is not cellular, and can include personal area networks (such as Bluetooth), local area networks (such as WiFi), or wide area networks (such as WiMax), or other wireless communication, or a combination. Wireless communication refers to transfer of data through the use of modulated electromagnetic radiation through a non-solid medium. Wired communication occurs through a solid communication medium.

Peripheral connections 880 include hardware interfaces and connectors, as well as software components (e.g., drivers, protocol stacks) to make peripheral connections. It will be understood that system 800 could both be a peripheral device (“to” 882) to other computing devices, as well as have peripheral devices (“from” 884) connected to it. System 800 commonly has a “docking” connector to connect to other computing devices for purposes such as managing (e.g., downloading, uploading, changing, synchronizing) content on system 800. Additionally, a docking connector can allow system 800 to connect to certain peripherals that allow system 800 to control content output, for example, to audiovisual or other systems.

In addition to a proprietary docking connector or other proprietary connection hardware, system 800 can make peripheral connections 880 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), or other type.

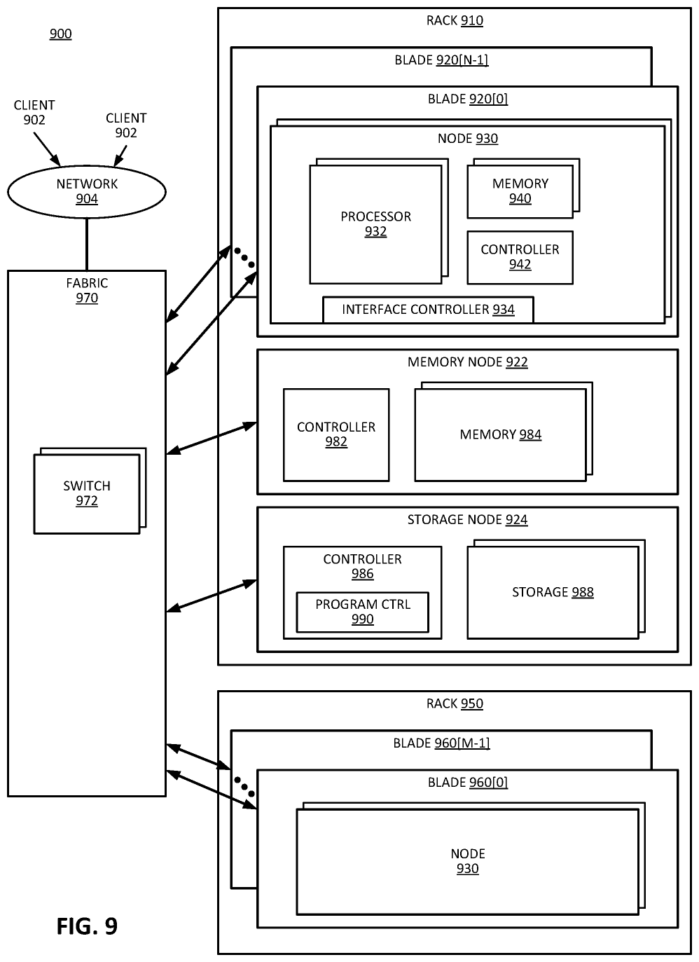

FIG. 9 is a block diagram of an example of a multi-node network in which multideck program verify can be implemented. In one example, system 900 represents a data center. In one example, system 900 represents a server farm. In one example, system 900 represents a data cloud or a processing cloud.

System 800 represents a system with storage in accordance with an example of system 100 or system 202 or system 204. In one example, controller 986 includes program control (CTRL) 990. Program control 990 enables system 900 to implement verify on multiple subblocks of storage 988 simultaneously, in accordance with any example herein.

One or more clients 902 make requests over network 904 to system 900. Network 904 represents one or more local networks, or wide area networks, or a combination. Clients 902 can be human or machine clients, which generate requests for the execution of operations by system 900. System 900 executes applications or data computation tasks requested by clients 902.

In one example, system 900 includes one or more racks, which represent structural and interconnect resources to house and interconnect multiple computation nodes. In one example, rack 910 includes multiple nodes 930. In one example, rack 910 hosts multiple blade components, blade 920[0], . . . , blade 920[N-1], collectively blades 920. Hosting refers to providing power, structural or mechanical support, and interconnection. Blades 920 can refer to computing resources on printed circuit boards (PCBs), where a PCB houses the hardware components for one or more nodes 930. In one example, blades 920 do not include a chassis or housing or other “box” other than that provided by rack 910. In one example, blades 920 include housing with exposed connector to connect into rack 910. In one example, system 900 does not include rack 910, and each blade 920 includes a chassis or housing that can stack or otherwise reside in close proximity to other blades and allow interconnection of nodes 930.

System 900 includes fabric 970, which represents one or more interconnectors for nodes 930. In one example, fabric 970 includes multiple switches 972 or routers or other hardware to route signals among nodes 930. Additionally, fabric 970 can couple system 900 to network 904 for access by clients 902. In addition to routing equipment, fabric 970 can be considered to include the cables or ports or other hardware equipment to couple nodes 930 together. In one example, fabric 970 has one or more associated protocols to manage the routing of signals through system 900. In one example, the protocol or protocols is at least partly dependent on the hardware equipment used in system 900.

As illustrated, rack 910 includes N blades 920. In one example, in addition to rack 910, system 900 includes rack 950. As illustrated, rack 950 includes M blade components, blade 960[0], . . . , blade 960[M-1], collectively blades 960. M is not necessarily the same as N; thus, it will be understood that various different hardware equipment components could be used, and coupled together into system 900 over fabric 970. Blades 960 can be the same or similar to blades 920. Nodes 930 can be any type of node and are not necessarily all the same type of node. System 900 is not limited to being homogenous, nor is it limited to not being homogenous.

The nodes in system 900 can include compute nodes, memory nodes, storage nodes, accelerator nodes, or other nodes. Rack 910 is represented with memory node 922 and storage node 924, which represent shared system memory resources, and shared persistent storage, respectively. One or more nodes of rack 950 can be a memory node or a storage node.

Nodes 930 represent examples of compute nodes. For simplicity, only the compute node in blade 920[0] is illustrated in detail. However, other nodes in system 900 can be the same or similar. At least some nodes 930 are computation nodes, with processor (proc) 932 and memory 940. A computation node refers to a node with processing resources (e.g., one or more processors) that executes an operating system and can receive and process one or more tasks. In one example, at least some nodes 930 are server nodes with a server as processing resources represented by processor 932 and memory 940.

Memory node 922 represents an example of a memory node, with system memory external to the compute nodes. Memory nodes can include controller 982, which represents a processor on the node to manage access to the memory. The memory nodes include memory 984 as memory resources to be shared among multiple compute nodes.

Storage node 924 represents an example of a storage server, which refers to a node with more storage resources than a computation node, and rather than having processors for the execution of tasks, a storage server includes processing resources to manage access to the storage nodes within the storage server. Storage nodes can include controller 986 to manage access to the storage 988 of the storage node.

In one example, node 930 includes interface controller 934, which represents logic to control access by node 930 to fabric 970. The logic can include hardware resources to interconnect to the physical interconnection hardware. The logic can include software or firmware logic to manage the interconnection. In one example, interface controller 934 is or includes a host fabric interface, which can be a fabric interface in accordance with any example described herein. The interface controllers for memory node 922 and storage node 924 are not explicitly shown.

Processor 932 can include one or more separate processors. Each separate processor can include a single processing unit, a multicore processing unit, or a combination. The processing unit can be a primary processor such as a CPU (central processing unit), a peripheral processor such as a GPU (graphics processing unit), or a combination. Memory 940 can be or include memory devices represented by memory 940 and a memory controller represented by controller 942.

In general with respect to the descriptions herein, in one aspect, a storage device includes: a nonvolatile storage medium having storage cells in subblocks; and a media controller to program the storage cells and perform a program verify of the storage cells, including to apply a verify read pulse to multiple subblocks simultaneously, count a number of bitlines of the multiple subblocks that do not discharge in response to the verify read pulse, and pass the program verify of the storage cells if the number is within an expected range.

In accordance with one example of the storage device, the multiple subblocks are a subset of a total number of subblocks. In accordance with any preceding example of the storage device, in one example, the nonvolatile storage medium has 16 total subblocks, and the multiple subblocks comprise 6 of the 16 total subblocks. In accordance with any preceding example of the storage device, in one example, the expected range comprises a range based on a statistical analysis for healthy programming. In accordance with any preceding example of the storage device, in one example, the expected range comprises an acceptable error tail. In accordance with any preceding example of the storage device, in one example, the media controller is to reduce the expected range based on the acceptable error tail. In accordance with any preceding example of the storage device, in one example, the media controller is to perform the program verify on multiple subblocks simultaneously when the nonvolatile storage medium is in single level cell (SLC) mode. In accordance with any preceding example of the storage device, in one example, the count comprises a count of a number of bytes of bitlines. In accordance with any preceding example of the storage device, in one example, the nonvolatile storage medium comprises a three-dimensional (3D) NAND storage medium.

In general with respect to the descriptions herein, in one aspect, a system includes: a processor device; and a storage device coupled to the processor device, the storage device including a nonvolatile storage medium having storage cells in subblocks; and a media controller to program the storage cells and perform a program verify of the storage cells, including to apply a verify read pulse to multiple subblocks simultaneously, count a number of bitlines of the multiple subblocks that do not discharge in response to the verify read pulse, and pass the program verify of the storage cells if the number is within an expected range.

In accordance with one example of the system, in one example, the multiple subblocks are a subset of a total number of subblocks. In accordance with any preceding example of the system, in one example, the nonvolatile storage medium has 16 total subblocks, and the multiple subblocks comprise 6 of the 16 total subblocks. In accordance with any preceding example of the system, in one example, the expected range comprises a range based on a statistical analysis for healthy programming. In accordance with any preceding example of the system, in one example, the expected range comprises an acceptable error tail. In accordance with any preceding example of the system, in one example, the media controller is to reduce the expected range based on the acceptable error tail. In accordance with any preceding example of the system, in one example, the nonvolatile storage medium comprises a three-dimensional (3D) NAND storage medium. In accordance with any preceding example of the system, in one example, the processor device comprises a multicore processor. In accordance with any preceding example of the system, in one example, the system includes a display communicatively coupled to the processor device. In accordance with any preceding example of the system, in one example, the system includes a battery to power the system. In accordance with any preceding example of the system, in one example, the system includes a network interface circuit to couple with a remote device over a network connection.

In general with respect to the descriptions herein, in one aspect, a method for performing read verify in a storage device includes: programming storage cells of a nonvolatile storage medium; and performing verify of the storage cells, including applying a verify read pulse to multiple subblocks simultaneously; counting a number of bitlines of the multiple subblocks that do not discharge in response to the verify read pulse; and passing the verify of the storage cells if the number is within an expected range.

In accordance with one example of the method, the expected range comprises a range based on a statistical analysis for healthy programming. In accordance with any preceding example of the method, in one example, the expected range comprises an acceptable error tail, wherein passing the verify of the storage cells comprises passing the expected range based on the acceptable error tail.

Flow diagrams as illustrated herein provide examples of sequences of various process actions. The flow diagrams can indicate operations to be executed by a software or firmware routine, as well as physical operations. A flow diagram can illustrate an example of the implementation of states of an FSM (finite state machine), which can be implemented in hardware and/or software. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted; thus, not all implementations will perform all actions.

To the extent various operations or functions are described herein, they can be described or defined as software code, instructions, configuration, and/or data. The content can be directly executable (“object” or “executable” form), source code, or difference code (“delta” or “patch” code). The software content of what is described herein can be provided via an article of manufacture with the content stored thereon, or via a method of operating a communication interface to send data via the communication interface. A machine readable storage medium can cause a machine to perform the functions or operations described, and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

Besides what is described herein, various modifications can be made to what is disclosed and implementations of the invention without departing from their scope. Therefore, the illustrations and examples herein should be construed in an illustrative, and not a restrictive sense. The scope of the invention should be measured solely by reference to the claims that follow.

What is claimed is:

1. A storage device comprising:
a nonvolatile storage medium having storage cells in subblocks; and
a media controller to program the storage cells and perform a program verify of the storage cells, including to apply a verify read pulse to multiple subblocks simultaneously, count a number of bitlines of the multiple subblocks that do not discharge in response to the verify read pulse, and pass the program verify of the storage cells if the number is within an expected range.

2. The storage device of claim 1, wherein the multiple subblocks are a subset of a total number of subblocks.

3. The storage device of claim 2, wherein the nonvolatile storage medium has 16 total subblocks, and the multiple subblocks comprise 6 of the 16 total subblocks.

4. The storage device of claim 1, wherein the expected range comprises a range based on a statistical analysis for healthy programming.

5. The storage device of claim 1, wherein the expected range comprises an acceptable error tail.

6. The storage device of claim 5, wherein the media controller is to reduce the expected range based on the acceptable error tail.

7. The storage device of claim 1, wherein the media controller is to perform the program verify on multiple subblocks simultaneously when the nonvolatile storage medium is in single level cell (SLC) mode.

8. The storage device of claim 1, wherein the count comprises a count of a number of bytes of bitlines.

9. The storage device of claim 1, wherein the nonvolatile storage medium comprises a three-dimensional (3D) NAND storage medium.

10. A system comprising:
a processor device; and
a storage device coupled to the processor device, the storage device including
a nonvolatile storage medium having storage cells in subblocks; and
a media controller to program the storage cells and perform a program verify of the storage cells, including to apply a verify read pulse to multiple subblocks simultaneously, count a number of bitlines of the multiple subblocks that do not discharge in response to the verify read pulse, and pass the program verify of the storage cells if the number is within an expected range.

11. The system of claim 10, wherein the multiple subblocks are a subset of a total number of subblocks.

12. The system of claim 11, wherein the nonvolatile storage medium has 16 total subblocks, and the multiple subblocks comprise 6 of the 16 total subblocks.

13. The system of claim 10, wherein the expected range comprises a range based on a statistical analysis for healthy programming.

14. The system of claim 10, wherein the expected range comprises an acceptable error tail.

15. The system of claim 14, wherein the media controller is to reduce the expected range based on the acceptable error tail.

16. The system of claim 10, wherein the nonvolatile storage medium comprises a three-dimensional (3D) NAND storage medium.

17. The system of claim 10,
wherein the processor device comprises a multicore processor;
further comprising a display communicatively coupled to the processor device;
further comprising a battery to power the system; or
further comprising a network interface circuit to couple with a remote device over a network connection.

18. A method for performing read verify in a storage device, comprising:
programming storage cells of a nonvolatile storage medium; and
performing verify of the storage cells, including
applying a verify read pulse to multiple subblocks simultaneously;
counting a number of bitlines of the multiple subblocks that do not discharge in response to the verify read pulse; and
passing the verify of the storage cells if the number is within an expected range.

19. The method of claim 18, wherein the expected range comprises a range based on a statistical analysis for healthy programming.

20. The method of claim 18, wherein the expected range comprises an acceptable error tail, wherein passing the verify of the storage cells comprises passing the expected range based on the acceptable error tail.
